(19) United States
(12) Patent Application Publication
(10) Pub. No.: US 2025/0219600 A1
(43) Pub. Date: Jul. 3, 2025

(54) AMPLIFICATION DEVICE AND OPERATION METHOD THEREOF

(71) Applicant: SAMSUNG ELECTRONICS CO., LTD., SUWON-SI (KR)

(72) Inventor: Jihun LEE, Suwon-si (KR)

(21) Appl. No.: 18/977,238

(22) Filed: Dec. 11, 2024

(30) Foreign Application Priority Data
Dec. 29, 2023 (KR) 10-2023-0197631
Mar. 13, 2024 (KR) 10-2024-0035472

(51) Int. Cl. H03F 3/217; H03F 3/45

(52) U.S. Cl. CPC H03F 3/2171; H03F 3/45183; H03F 2200/03; H03F 2200/351

(57) ABSTRACT

An amplification device including: a pulse generation circuit configured to generate a pulse signal from an input signal and a tri-wave signal; a driver circuit configured to output an output signal corresponding to the pulse signal, based on a first pair of operating voltages among a plurality of operating voltages; and a tri-wave generation circuit configured to generate the tri-wave signal, and to adjust a level of the tri-wave signal in proportion to a second pair of operating voltages, when the first pair of operating voltages is changed to the second pair of operating voltages.

### CROSS-REFERENCE TO RELATED APPLICATIONS

This application claims priority under 35 U.S.C. § 119 to Korean Patent Application Nos. 10-2023-0197631 filed on Dec. 29, 2023, and 10-2024-0035472 filed on Mar. 13, 2024, in the Korean Intellectual Property Office, the disclosures of which are incorporated by reference herein in their entireties.

### TECHNICAL FIELD

Embodiments of the present disclosure described herein relate to an amplification device and a method of operating the same.

### DISCUSSION OF RELATED ART

Mobile devices, such as smartphones, often require longer battery life, which can be achieved by reducing quiescent power consumption or improving power efficiency. However, when switching amplifiers, such as class-D amplifiers, are used to achieve high power efficiency, quiescent current can become an issue. One approach to mitigate this is by using multi-level operating voltages to reduce quiescent current, though this may compromise the linearity of the amplifiers.

### SUMMARY

Embodiments of the present disclosure provide an amplification device capable of improving linearity and a method of operating the same.

According to an embodiment of the present disclosure, an amplification device includes: a pulse generation circuit configured to generate a pulse signal from an input signal and a tri-wave signal; a driver circuit configured to output an output signal corresponding to the pulse signal, based on a first pair of operating voltages among a plurality of operating voltages; and a tri-wave generation circuit configured to generate the tri-wave signal, and to adjust a level of the tri-wave signal in proportion to a second pair of operating voltages, when the first pair of operating voltages is changed to the second pair of operating voltages.

According to an embodiment of the present disclosure, an amplification device includes: a pair of amplification circuits configured to generate differential pulse signals from differential input signals, a common mode signal, and differential tri-wave signals, and to output differential output signals corresponding to the differential pulse signals, based on a first pair of operating voltages; and a tri-wave generation circuit configured to generate the differential tri-wave signals, and to adjust levels of the differential tri-wave signals in proportion to a second pair of operating voltages, when the first pair of operating voltages is switched to the second pair of operating voltages.

According to an embodiment of the present disclosure, a method of operating an amplification device includes: generating a pulse signal from an input signal and a tri-wave signal; outputting an output signal corresponding to the pulse signal, based on a first pair of operating voltages; switching the first pair of operating voltages to a second pair of operating voltages; and adjusting a level of the tri-wave signal in proportion to a second pair of operating voltages, when the first pair of operating voltages is switched to the second pair of operating voltages.

### BRIEF DESCRIPTION OF THE DRAWINGS

The above and other features of the present disclosure will become apparent by describing in detail embodiments thereof with reference to the accompanying drawings.

FIG. 1 illustrates an amplification device, according to some embodiments.

FIG. 2 illustrates a pulse generation circuit, according to some embodiments.

FIG. 3 illustrates a driver circuit, according to some embodiments.

FIG. 4 is a circuit diagram of a switching network circuit of FIG. 3, according to some embodiments.

FIG. 5 illustrates a tri-wave generation circuit, according to some embodiments.

FIG. 6 illustrates an amplification device, according to some embodiments.

FIGS. 7 and 8 illustrate operating waveforms of an amplification device, according to some embodiments.

FIG. 9 is a circuit diagram of a reference voltage generation circuit, according to some embodiments.

FIG. 10 is a circuit diagram of a reference tri-wave generation circuit, according to some embodiments.

FIG. 11 is a circuit diagram of an adjustment circuit, according to some embodiments.

FIG. 12 illustrates a waveform of a tri-wave signal output through a tri-wave generation circuit, according to some embodiments.

FIG. 13 is a flowchart illustrating a method of operating an amplification device, according to some embodiments.

FIG. 14 illustrates an audio device, according to some embodiments.

### DETAILED DESCRIPTION OF THE EMBODIMENTS

Hereinafter, embodiments of the present disclosure will be described in detail, providing clarity and specificity sufficient for those skilled in the art to implement the present disclosure.

FIG. 1 illustrates an amplification device, according to some embodiments.

Referring to FIG. 1, an amplification device 100 according to some embodiments may include a pulse generation circuit 110, a driver circuit 120, and a tri-wave generation circuit 130.

The pulse generation circuit 110 may be configured to generate a pulse signal PS

from an input signal IN and a tri-wave signal TRI generated by the tri-wave generation circuit 130. For example, when the amplification device 100 is applied to an audio system, the input signal IN may be a signal converted from an audio signal, which is a digital signal, to an analog signal. The tri-wave signal TRI is generated by the tri-wave generation circuit 130 and may be a non-sinusoidal wave having a triangular shape. In other words, the tri-wave signal TRI may have a non-sinusoidal, triangular waveform. The tri-wave signal TRI can be referred to as a triangular wave signal. The tri-wave signal TRI may be a reference signal with respect to the input signal IN.

According to some embodiments, a level of the tri-wave signal TRI may be adjusted while maintaining an equal distribution of a common mode voltage. In this case, the pulse generation circuit 110 will generate the pulse signal PS based on the tri-wave signal TRI with the adjusted level.

According to some embodiments, the pulse generation circuit 110 may compare the input signal IN with the tri-wave signal TRI and, as a result, generate the pulse signal PS with a duty cycle proportional to an instantaneous value of the input signal IN. In detail, the pulse generation circuit 110 may generate the pulse signal PS for the input signal IN based on Pulse Width Modulation (PWM).

The driver circuit 120 may be configured to output an output signal OUT corresponding to the pulse signal PS. The output signal OUT may be expressed as a binary signal with a pulse width proportional to the input signal IN.

According to some embodiments, the driver circuit 120 may operate based on a plurality of operating voltages and a ground voltage. The plurality of operating voltages may have different voltage levels, forming a multi-level configuration. The plurality of operating voltages may include voltages VDD1 to VDDn and a ground voltage. The plurality of operating voltages may be provided to the driver circuit 120 through different supply lines.

According to some embodiments, a ground voltage and “n” operating voltages VDD1 to VDDn may be provided to the driver circuit 120, where “n” is a natural number that can be configured in various ways, depending on requirements and implementation examples of the amplification device 100.

The driver circuit 120 may output the output signal OUT based on a pair of operating voltages selected from among the plurality of operating voltages. In this case, the output signal OUT may be output in the form of a pulse of a high level voltage and a low level voltage according to levels of a pair of operating voltages. In other words, the output signal OUT may be generated as a pulse alternating between a high-level voltage and a low-level voltage, based on the levels of the pair of operating voltages.

According to some embodiments, a pair of operating voltages may be switched based on the input signal IN. In detail, the driver circuit 120 may adjust a first pair of operating voltages to a second pair of operating voltages in response to changes in the level of the input signal IN. For example, the driver circuit 120 may operate in a low-power mode using a low-level operating voltage when the input signal IN is at a low level. Alternatively, the driver circuit 120 may operate in a high-power mode using a high-level operating voltage when the input signal IN is at a high-level.

When a pair of operating voltages is switched according to some of the above-described embodiments, the duty ratio of the output signal OUT should also change. However, in a typical amplification device 100 with a limited bandwidth, the duty ratio remains constant if the tri-wave, which serves as the reference signal, is unchanged. Although the duty ratio remains the same the level of the output signal OUT changes with the switching of a pair of operating voltages, which can lead to a deterioration in the linearity of the output signal OUT. To address this issue, it may be necessary to appropriately adjust the duty ratio of the output signal OUT to maintain linearity.

The tri-wave generation circuit 130 may be configured to generate the tri-wave signal TRI. For example, the tri-wave generation circuit 130 may be implemented with an oscillator. According to some embodiments, the tri-wave generation circuit 130 may output clock signals for driving the amplification device 100 along with the tri-wave signal TRI.

According to some embodiments, the tri-wave generation circuit 130 may generate the tri-wave signal TRI with a level that changes based on the switching of a pair of operating voltages. For example, when the first pair of operating voltages is switched to the second pair of operating voltages, the tri-wave generation circuit 130 may adjust the level (or amplitude) of the tri-wave signal TRI in proportion to the second pair of operating voltages. In this context, ‘adjusted in proportion to the switched second pair of operating voltages’ means that when the level of the output signal OUT changes due to the switching of the operating voltages, the level of the tri-wave signal TRI is adjusted to modify the duty ratio in accordance with the level of the changed output signal OUT. In detail, the tri-wave generation circuit 130 may adjust the level of the tri-wave signal TRI such that the duty ratio of the output signal OUT is adjusted according to the level of the changed output signal OUT according to the switching of the operating voltages. In other words, the tri-wave generation circuit 130 adjusts the level of the tri-wave signal TRI to ensure that the duty ratio of the output signal OUT is appropriately modified in response to changes in the output signal OUT resulting from the switching of the operating voltages.

For example, when the level of the output signal OUT increases after the switching of the operating voltages, the tri-wave generation circuit 130 may generate the tri-wave signal TRI having a higher level. Alternatively, when the level of the output signal OUT decreases after the switching of the operating voltages, the tri-wave generation circuit 130 may generate the tri-wave signal TRI having a lower level.

According to some embodiments, the tri-wave generation circuit 130 may generate the tri-wave signal TRI having the same common mode voltage. In detail, even if the level of the tri-wave signal TRI changes due to dynamic voltage switching, all tri-wave signals TRI may have the same common mode voltage.

When operating with multi-level voltages, the amplification device 100 according to the above-described embodiments may adjust the level of the tri-wave signal TRI in response to the switched operating voltages. By adjusting the level of the tri-wave signal TRI such that the output signal OUT has an appropriate duty ratio corresponding to its level change, the deterioration in linearity of the amplification device 100 can be mitigated.

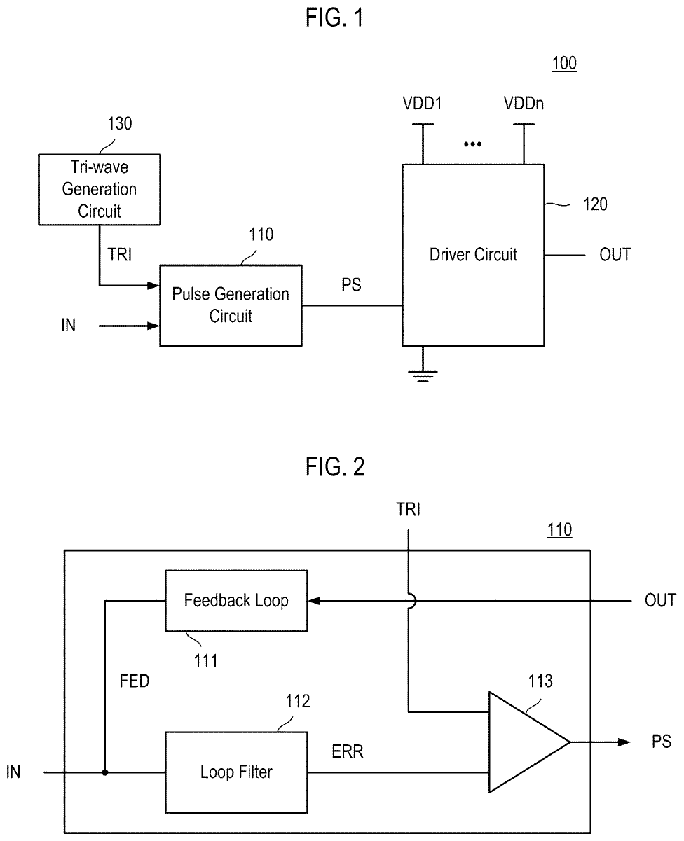

FIG. 2 illustrates a pulse generation circuit, according to some embodiments.

Referring to FIG. 2, the pulse generation circuit 110 according to some embodiments may include a feedback loop 111, a loop filter 112, and a comparator 113.

The feedback loop 111 is connected to an input terminal of the loop filter 112 and an output terminal where the output signal OUT is output. The feedback loop 111 is configured to provide a fed back signal FED to the input terminal of the loop filter 112. The fed back signal FED may correspond to the output signal OUT provided to the loop filter 112 through the feedback loop 111.

The input terminal of the loop filter 112 is provided with the input signal IN and the fed back signal FED. The signal at the input terminal of the loop filter 112 may represent a difference between the input signal IN and the fed back signal FED. The loop filter 112 may be configured to output an error signal ERR based on the filtered input signal IN and fed back signal FED. By performing this filtering operation, the loop filter 112 helps minimize distortion in the output signal OUT of the amplification device 100. According to some embodiments, the loop filter 112 may be implemented as a high-order filter to improve filtering performance. According to some embodiments, the loop filter 112 may include one or more integrators.

The error signal ERR output through the loop filter 112 may be a sinusoidal wave. In some embodiments, the frequency of the tri-wave signal TRI may be set sufficiently higher than the frequency of the error signal ERR.

The comparator 113 may generate the pulse signal PS by comparing the error signal ERR with the tri-wave signal TRI. The tri-wave signal TRI may be provided through the tri-wave generation circuit 130 of FIG. 1 and may have an adjusted level depending on the switching of the operating voltages. The comparator 113 may generate the pulse signal PS, which is a binary waveform, based on the comparison between the levels of the error signal ERR and the tri-wave signal TRI. Consequently, the pulse signal PS is output with a duty ratio that reflects an amplitude of the error signal ERR.

The pulse generation circuit 110 according to the above-described embodiments may generate the pulse signal PS based on the tri-wave signal TRI with an adjust level when the multi-level operating voltages are switched.

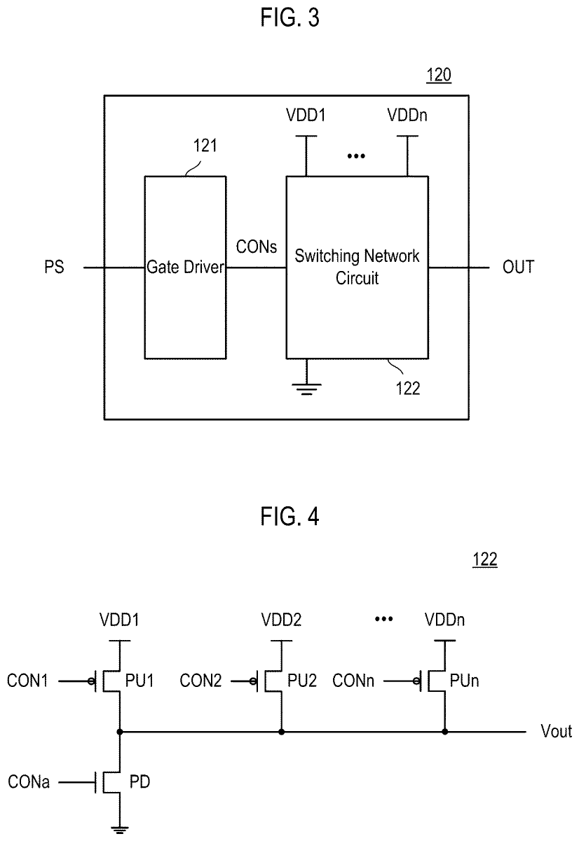

FIG. 3 illustrates a driver circuit, according to some embodiments.

Referring to FIG. 3, the driver circuit 120 according to some embodiments may include a gate driver 121 and a switching network circuit 122.

The gate driver 121 may be configured to apply a plurality of control signals CONs for controlling the switching network circuit 122 to the switching network 122 from the pulse signal PS generated by the comparator of FIG. 2. Each of the plurality of control signals CONs may be used to select and control several transistors included in the switching network circuit 122. The gate driver 121 may generate the plurality of control signals CONs to drive the switching network circuit 122 according to the duty ratio of the pulse signal PS.

The switching network circuit 122 may be configured to output the output signal OUT through a pull-up or a pull-down device corresponding to a pair of operating voltages among a plurality of operating voltages. According to some embodiments, a pair of operating voltages may be switched by the plurality of control signals CONs.

FIG. 4 is a circuit diagram of a switching network circuit of FIG. 3, according to some embodiments.

Referring to FIG. 4, the switching network circuit 122 according to some embodiments may include a plurality of pull-up transistors PU1 to PUn and a pull-down transistor PD. In addition to what is illustrated, a plurality of pull-down transistors PD may also be included.

The plurality of pull-up transistors PU1 to PUn may be implemented with P-type Metal Oxide Semiconductor Field Effect Transistors (PMOSFETs). In this case, the plurality of pull-up transistors PU1 to PUn may include sources connected to a plurality of operating voltages, gates receiving some of the plurality of control signals CONs, and drains connected to an output terminal through which the output signal OUT is output. Different multi-level operating voltages may be applied to the source of each pull-up transistor. When “n” operating voltages are applied, “n” pull-up transistors may be configured as well.

The pull-down transistor PD may be implemented with N-type Metal Oxide Semiconductor Field Effect Transistors (NMOSFETs). In this case, the pull-down transistor PD may include a drain connected to the output terminal, a gate that receives one control signal CONa from the plurality of control signals CONs, and a source connected to ground.

The plurality of pull-up transistors PU1 to PUn may perform a pull-up operation on the output voltage at the output terminal based on a plurality of operating voltages, and may perform a pull-down operation on the output voltage to a ground voltage. A pair of transistors may be selected from among the plurality of pull-up transistors PU1 to PUn and the pull-down transistor PD through the plurality of control signals, and the selected pair of transistors may perform the pull-up and pull-down operations according to a duty ratio.

Ultimately, since a pair of transistors operating according to a pair of operating voltages are selected through the plurality of control signals, the plurality of control signals are configured to select a first pair of operating voltages or a different second pair of operating voltages from among the plurality of operating voltages depending on the level of the input signal IN.

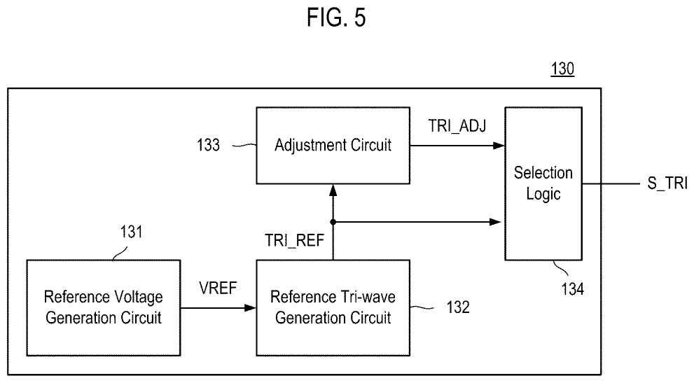

FIG. 5 illustrates a tri-wave generation circuit, according to some embodiments.

Referring to FIG. 5, the tri-wave generation circuit 130 according to some embodiments may include a reference voltage generation circuit 131, a reference tri-wave generation circuit 132, an adjustment circuit 133, and selection logic 134.

The reference voltage generation circuit 131 may be configured to generate a reference voltage VREF to generate a reference tri-wave. For example, the reference voltage generation circuit 131 may generate the reference voltage VREF from one (e.g., a battery voltage of an amplification device) of the operating voltages, or may buffer the generated reference voltage VREF.

The reference tri-wave generation circuit 132 may be configured to generate a reference tri-wave signal TRI_REF from the reference voltage VREF. The reference tri-wave signal TRI_REF may be a signal used for a specific pair of operating voltages. For example, the reference tri-wave generation circuit 132 may be configured with a structure in which the reference voltage VREF oscillates depending on an amplifier and a capacitor. The reference tri-wave signal TRI_REF may have a specific level or amplitude. In this case, the reference tri-wave signal TRI_REF may oscillate based on the common mode voltage.

The adjustment circuit 133 may be configured to generate one or more adjusted tri-wave signals TRI_ADJ having different levels from the generated reference tri-wave signal TRI_REF. The one or more adjusted tri-wave signals TRI_ADJ may have a level or amplitude different from the reference tri-wave signal TRI_REF. The adjustment circuit 133 may be implemented according to various structures and methods to generate the tri-wave signal TRI that shares the same common mode voltage as the reference tri-wave signal TRI_REF but differs in level from that of the reference tri-wave signal TRI_REF. As an example, the adjustment circuit 133 may utilize a voltage distribution structure with a variable resistor, thereby generating one or more adjusted tri-wave signals TRI_ADJ with levels that differ from the level of the reference tri-wave signal TRI_REF.

The selection logic 134 may be configured to select a tri-wave signal S_TRI from either the reference tri-wave signal TRI_REF or one or more adjusted tri-wave signals TRI_ADJ when the first pair of operating voltages is changed to the second pair of operating voltages. The selection logic 134 may select the tri-wave signal S_TRI having a level that ensures the output signal OUT has a duty ratio corresponding to the new voltage levels, taking into account the switched pair of operating voltages. According to some embodiments, the selection logic 134 may be implemented to detect a pair of switched operating voltages in the driver circuit 120.

The tri-wave generation circuit 130 according to the above-described embodiments is merely an example. It is understood that various other tri-wave generation circuits 130, utilizing different structures or methods to generate tri-wave signals TRI with the same common mode voltage but different amplitude levels, are included in embodiments of the present disclosure.

The tri-wave generation circuit 130 according to the above-described embodiments may generate the tri-wave signal TRI with a level that maintains the linearity of the output signal OUT taking into account the level of the pair of switched operating voltages.

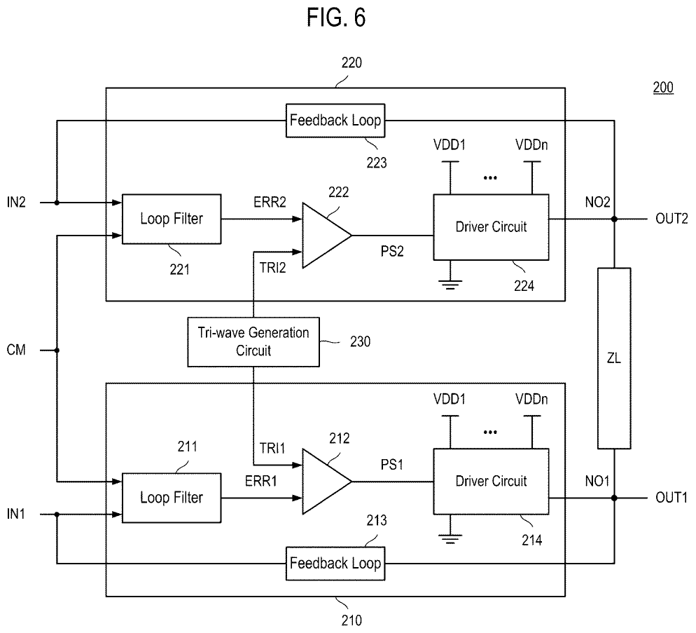

FIG. 6 illustrates an amplification device, according to some embodiments.

Referring to FIG. 6, an amplification device 200 according to some embodiments may include a pair of amplification circuits 210 and 220 and a tri-wave generation circuit 230.

The pair of amplification circuits 210 and 220 may be configured to generate differential pulse signals PS1 and PS2 from differential input signals IN1 and IN2, a common mode signal CM, and differential tri-wave signals TRI1 and TRI2. The pair of amplification circuits 210 and 220 may further be configured to output differential output signals OUT1 and OUT2 respectively corresponding to the differential pulse signals PS1 and PS2, based on a first pair of operating voltages among a plurality of operating voltages including the voltages VDD1 to VDDn and the ground voltage. According to some embodiments, the pair of amplification circuits 210 and 220 may adjust a first pair of operating voltages to the second pair of operating voltages based on changes in the levels of the differential input signals IN1 and IN2.

The pair of amplification circuits 210 and 220 may include the first amplification circuit 210 and the second amplification circuit 220, which are connected to a load ZL. According to some embodiments, each amplification circuit 210 and 220 may be configured according to the embodiments of FIGS. 1 to 5. In detail, the first amplification circuit 210 may be configured the same as the second amplification circuit 220. However, when the signals associated with the first amplification circuit 210 correspond to one of the pair of differential signals, the signals associated with the second amplification circuit 220 may correspond to the other differential signal. In detail, the signals associated with the first amplification circuit 210 and the signals associated with the second amplification circuit 220 may have different phases.

According to some embodiments, the pair of amplification circuits 210 and 220 may include a pair of loop filters 211 and 221, a pair of comparators 212 and 222, a pair of feedback loops 213 and 223, and a pair of driver circuits 214 and 224. The first and second loop filters 211 and 221, the first and second comparators 212 and 222, and the first and second feedback loops 213 and 223 may be configured according to the embodiments of FIG. 2 described above.

The pair of loop filters 211 and 221 may be configured to output differential error signals ERR1 and ERR2 based on the filtering of the differential input signals IN1 and IN2, the common mode signal CM, and signals fed back from the differential output signals OUT1 and OUT2. Each of the pair of loop filters 211 and 221 receives a signal corresponding to a difference between one input signal and one fed-back signal, along with the common mode signal CM. The differential error signals ERR1 and ERR2 are then output as signals that vary the common mode voltage in correspondence with the common mode signal CM.

The pair of comparators 212 and 222 may generate the differential pulse signals PS1 and PS2 by comparing the differential error signals ERR1 and ERR2 with the differential tri-wave signals TRI1 and TRI2, respectively. As an example, the first comparator may output a first pulse signal by comparing the first error signal with the first tri-wave signal.

The pair of feedback loops 213 and 223 is connected to input terminals of the pair of loop filters 211 and 221 and output terminals where the differential output signals OUT1 and OUT2 are output, respectively. The pair of feedback loops 213 and 223 may be configured to provide the fed back signals to the input terminals of the pair of loop filters 211 and 221. As an example, the first feedback loop 213 may be connected to the input terminal of the first loop filter 211 and a first output node NO1 through which the first output signal OUT1 is output. As another example, the second feedback loop 223 may be connected to the input terminal of the second loop filter 221 and a second output node NO2 through which the second output signal OUT2 is output.

The pair of driver circuits 214 and 224 may be configured to output the differential output signals OUT1 and OUT2 through the pull-up or pull-down operation corresponding to the first pair of operating voltages, based on the differential pulse signals PS1 and PS2. As an example, the first driver circuit 214 may output a first output signal OUT1 through the pull-up or pull-down operation based on the first pulse signal PS1. The first output signal OUT1 may have a polarity opposite to that of the first input signal IN1.

The tri-wave generation circuit 230 may be configured to generate differential tri-wave signals TRI1 and TRI2. According to some embodiments, the tri-wave generation circuit 230 may be configured according to the embodiment of FIG. 5. In detail, the tri-wave generation circuit 230 may include a reference voltage generation circuit configured to generate a reference voltage, a reference tri-wave generation circuit configured to generate differential reference tri-wave signals from the reference voltage, an adjustment circuit configured to generate a plurality of differential adjusted tri-wave signals having different levels from the differential reference tri-wave signals, and selection logic configured to select the differential tri-wave signals from among the differential reference tri-wave signals and a plurality of differential adjusted tri-wave signals when the first pair of operating voltages are changed to the second pair of operating voltages.

The generated first tri-wave signal TRI1 is provided to the first amplification circuit 210, and the second tri-wave signal TRI2 is provided to the second amplification circuit 220. The first tri-wave signal TRI1 and the second tri-wave signal TRI2 may have the same common mode voltage, amplitude level, and frequency. The amplitude level may vary depending on the switching of a pair of operating voltages.

According to some embodiments, the tri-wave generation circuit 230 may adjust the levels of the differential tri-wave signals TRI1 and TRI2 in proportion to the second pair of operating voltages when the first pair of operating voltages is changed to the second pair of operating voltages. For example, the tri-wave generation circuit 230 may adjust the level of the first tri-wave signal TRI1 such that the duty ratio of the first output signal OUT1, now at a changed level, is adjusted in response to the new operating voltage.

Therefore, in the amplification device 200 described in the above embodiments, even if the levels of the differential output signals OUT1 and OUT2 change due to the altered operating voltages, the duty ratios of the differential output signals OUT1 and OUT2 are adjusted through the level adjustment of the tri-wave signals. This adjustment helps prevent the deterioration of linearity of the differential output signals OUT1 and OUT2.

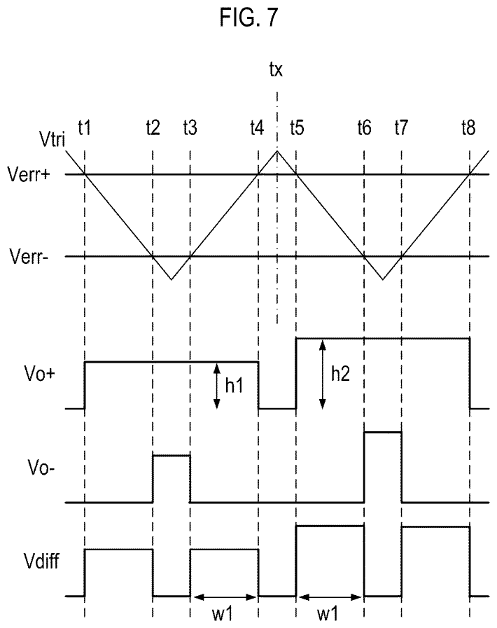

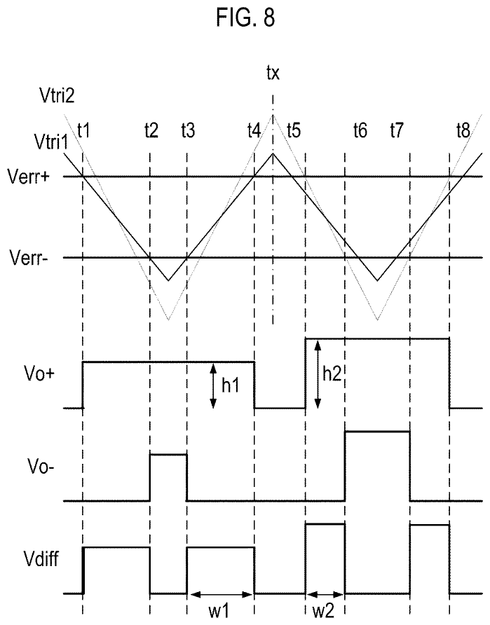

FIGS. 7 and 8 illustrate operating waveforms of an amplification device, according to some embodiments. As an example, FIG. 7 illustrates an operating waveform when the tri-wave is not adjusted according to the level, and FIG. 8 illustrates an operating waveform when the tri-wave is adjusted according to the level.

Referring to FIGS. 7 and 8, the waveforms of the tri-wave signal Vtri, differential error signals Verr+ and Verr−, differential output signals Vo+ and Vo−, and an effective output signal Vdiff are illustrated. The effective output signal Vdiff is an output signal corresponding to a difference between the differential output signals Vo+ and Vo−, and is a signal that is actually output to the load ZL. Additionally, it is assumed that the frequency of the tri-wave signal Vtri is sufficiently large compared to the frequencies of the differential error signals Verr+ and Verr−, and therefore the differential error signals Verr+ and Verr− are illustrated as DC components. In detail, the corresponding operating waveform will be understood as being for a very small time section.

The amplification device according to the above-described embodiments may

output the first output signal Vo+ by comparing the level of the tri-wave signal Vtri with the level of the first error signal Verr+. Additionally, the amplification device may output the second output signal Vo− by comparing the level of the same tri-wave signal Vtri with the level of the second error signal Verr−. Therefore, the first output signal Vo+ represents logic high in a section (e.g., t1 to t4) where the level of the first error signal Verr+ is higher than that of the tri-wave signal Vtri, and represents logic low in a section (e.g., t4 to t5) where the level of the first error signal Verr+ is lower than that of the tri-wave signal Vtri. In addition, the second output signal Vo− represents logic high in a section (e.g., t2 to t3) where the level of the second error signal Verr− is higher than that of the tri-wave signal Vtri, and represents logic low in a section (e.g., t1 to t2) where the level of the second error signal Verr− is lower than that of the tri-wave signal Vtri.

When the levels of a pair of operating voltages are switched based on a specific time “tx”, the levels of the differential output signals Vo+ and Vo− will also change. For example, when the level of the high voltage side of a pair of operating voltages increases, the level of the high voltage side, i.e., Vo+, of the differential output signals Vo+ and Vo− will also increase from h1 to h2.

However, when the duty ratio needs to be maintained within a limited bandwidth (i.e., when the same tri-wave signal is used without adjusting its level), the area of each pulse in the effective output signal Vdiff will change abruptly. This occurs because only the output level changes while the duty ratio of the differential output signals Vo+ and Vo− remains constant. As a result, the linearity of the amplification device may degrade due to the sudden changes in the effective output signal Vdiff.

In contrast, as illustrated in FIG. 8, when the levels of a pair of operating voltages are switched based on the specific time “tx”, the level of the tri-wave signal also changes. In some embodiments, the amplification device may adjust the level of a tri-wave signal Vtri1 at its peak (or lowest) point before the change occurs. Since a tri-wave signal Vtri2 after the change has an adjusted level, the pulse width of the differential output signals Vo+ and Vo− after the specific time “tx” changes accordingly. As a result of this change in pulse width, the pulse width of the effective output signal Vdiff also changes from w1 to w2. As an example, FIG. 8 illustrates a case where the level of the differential output signals Vo+ and Vo− increases (i.e., the level of the operating voltage increases), causing a decrease in the pulse widths of the differential output signals Vo+ and Vo− as well as the effective output signal Vdiff. In detail, the duty ratio of the output signal decreases. Due to this duty ratio change, the area of each pulse of the effective output signal Vdiff remains the same before and after the specific time “tx”.

Ultimately, despite the level switching of the pair of operating voltages, the duty ratio is adjusted appropriately (i.e., the duty ratio is adjusted to ensure that the area of each pulse of the effective output signal Vdiff remains the same before and after switching). As a result, the area of each pulse of the effective output signal Vdiff remains consistent, thereby resolving potential deterioration in the linearity of the output signal.

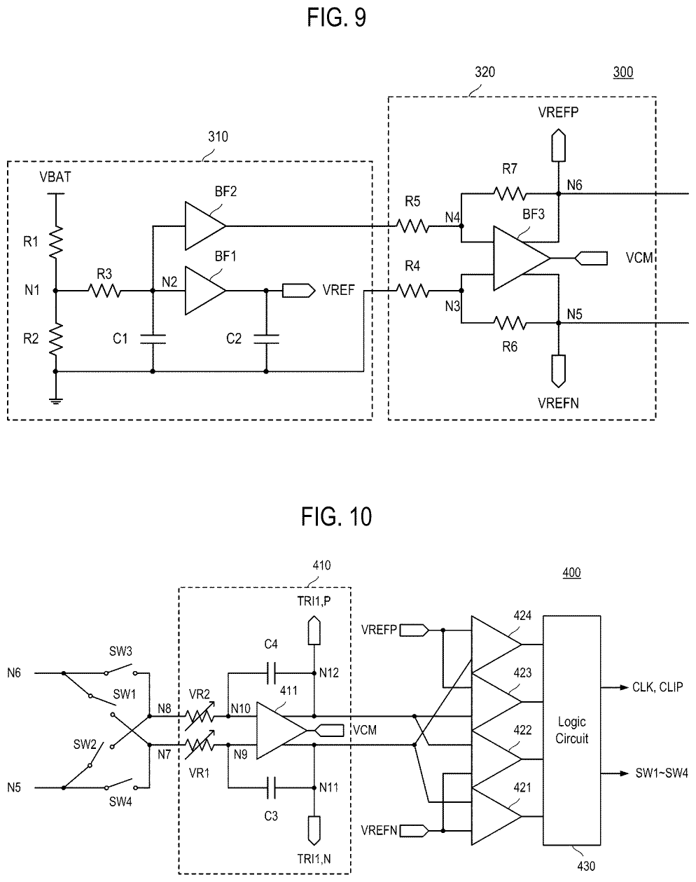

FIG. 9 is a circuit diagram of a reference voltage generation circuit 300, according to some embodiments.

Referring to FIG. 9, the reference voltage generation circuit 300 (or the reference voltage generation circuit 131 of FIG. 5 or the reference voltage generation circuit included in the tri-wave generation circuit 230 of FIG. 6) according to some embodiments may include a first stage circuit 310 and a second stage circuit 320.

The first stage circuit 310 is configured to generate the reference voltage VREF from an operating voltage VBAT. For example, the first stage circuit 310 may include a plurality of resistors, a plurality of capacitors, and a plurality of buffers.

The operating voltage VBAT is distributed to a first node N1 through the voltage division of a first resistor R1 and a second resistor R2, which are connected to the first node N1. This divided voltage is then applied to a plurality of buffers through a third resistor R3, which is connected between the first node N1 and a second node N2. In this configuration, the third resistor R3 may provide high impedance to a first buffer BF1 and a second buffer BF2. The voltage at the first node N1 may be 1/N times the operating voltage VBAT, where “N” is a real number greater than “0”.

A first capacitor C1 is connected to the second node N2, which corresponds to input terminals of the first buffer BF1 and the second buffer BF2. Additionally, a second capacitor C2 is connected to an output terminal of the first buffer BF1. The reference voltage VREF is output through the first buffer BF1 and the second buffer BF2. One end of each of the second resistor R2, the first capacitor C1, and the second capacitor C2 is connected to ground.

The first stage circuit 310 is connected to the second stage circuit 320 through the output terminal of the second buffer BF2 and a ground node. The second stage circuit 320 is connected to the first stage circuit 310 through a fourth resistor R4 and a fifth resistor R5. The fourth resistor R4 is connected to an input terminal of a third buffer BF3 through a third node N3, and the fifth resistor R5 is connected to the input terminal of the third buffer BF3 through a fourth node N4. The third buffer BF3 may buffer the reference voltage VREF based on a common mode voltage VCM and may output differential reference voltages VREFN and

VREFP. The first differential reference voltage VREFN is output to a fifth node N5 through a sixth resistor R6 connected to the third node N3, and the second differential reference voltage VREFP is output to a sixth node N6 through a seventh resistor R7 connected to the fourth node N4. The output differential reference voltages VREFN and VREFP may be used to generate the tri-wave signal.

According to some embodiments, the sixth resistor R6 is M times the resistance size of the fourth resistor R4, where “M” is a real number greater than “0”, and the seventh resistor R7 may is M times the resistance size of the fifth resistor R5. In this case, the first differential reference voltage VREFN may be expressed as

$${V}_{CM} - \frac{M - {V}_{BAT}}{2 N} ,$$

and the second differential reference voltage VREFP may be expressed as

$${V}_{CM} + \frac{M \cdot {B}_{BAT}}{2 N} .$$

FIG. 10 is a circuit diagram of a reference tri-wave generation circuit, according to some embodiments.

Referring to FIG. 10, a reference tri-wave generation circuit 400 (or the reference tri-wave generation circuit 132 of FIG. 5 or the reference tri-wave generation circuit included in the tri-wave generation circuit 230 of FIG. 6) according to some embodiments may include a plurality of switches SW1 to SW4, an oscillation circuit 410, a plurality of comparators 421 to 424, and a logic circuit 430.

The plurality of switches SW1 to SW4 may be turned on or turned off under the control of the logic circuit 430. The first switch SW1 and the second switch SW2 may operate together, and the third switch SW3 and the fourth switch SW4 may operate together. When the first switch SW1 and the second switch SW2 are turned on, the third switch SW3 and the fourth switch SW4 are turned off, the sixth node N6 and a seventh node N7 are connected to each other, and the fifth node N5 and an eighth node N8 are connected to each other. In contrast, when the first switch SW1 and the second switch SW2 are turned off, the third switch SW3 and the fourth switch SW4 are turned on, the sixth node N6 and the eighth node N8 are connected to each other, and the fifth node N5 and the seventh node N7 are connected to each other. The slope direction of the signal output from the oscillation circuit 410 is based on the operation of the plurality of switches SW1 to SW4, thereby generating the tri-wave signal.

The oscillation circuit 410 may be implemented with an integrator. A first variable resistor VR1 connected to the seventh node N7 is connected to a ninth node N9 corresponding to the input terminal of an amplifier 411, and a second variable resistor VR2 connected to the eighth node N8 is connected to a tenth node N10. For example, the first variable resistor VR1 and the second variable resistor VR2 may have the same variable resistance “R”.

Additionally, the common mode voltage VCM is applied to the amplifier 411. In the integrator structure of the oscillation circuit 410, a third capacitor C3 connected to the ninth node N9 is connected to an eleventh node N11 corresponding to an output terminal of the amplifier 411, and a fourth capacitor C4 connected to the tenth node N10 is connected to a twelfth node N12 corresponding to another output terminal of the amplifier 411. For example, the third capacitor C3 and the fourth capacitor C4 may have the same capacitance “C”.

Through oscillation of the oscillation circuit 410, differential reference tri-wave signals TRI1,N and TRI1,P are output to the eleventh node N11 and the twelfth node N12. In this case, the levels of the differential reference tri-wave signals TRI1,N and TRI1,P may change depending on resistance changes of the first variable resistor VR1 and the second variable resistor VR2. Additionally, the differential reference tri-wave signals TRI1,N and TRI1,P may oscillate based on the common mode voltage VCM.

The plurality of comparators 421 to 424 are connected to output terminals (i.e., the eleventh node N11 and the twelfth node N12) of the oscillation circuit 410, and the logic circuit 430 is connected to output terminals of the plurality of comparators 421 to 424. The first comparator 421 and the second comparator 422 are commonly provided with the first differential reference voltage VREFN, and the third comparator 423 and the fourth comparator 424 are commonly provided with the second differential reference voltage VREFP. The first comparator 421 compares the voltage at the eleventh node N11 with the first differential reference voltage VREFN and provides the comparison result to the logic circuit 430. The second comparator 422 compares the voltage at the twelfth node N12 with the first differential reference voltage VREFN and provides the comparison result to the logic circuit 430. The third comparator 423 compares the voltage at the twelfth node N12 with the second differential reference voltage VREFP and provides the comparison result to the logic circuit 430. The fourth comparator 424 compares the voltage at the eleventh node N11 with the second differential reference voltage VREFP and provides the comparison result to the logic circuit 430. The logic circuit 430 may use the comparison results to determine the switching timing of the plurality of switches SW1 to SW4.

The logic circuit 430 may determine the switching timing of the plurality of switches SW1 to SW4, including which switch to be turned on (or turned off), based on the comparison results received from the plurality of comparators 421 to 424. According to some embodiments, the logic circuit 430 may output a clock signal corresponding to the tri-wave signal and a clipping signal for detecting clipping.

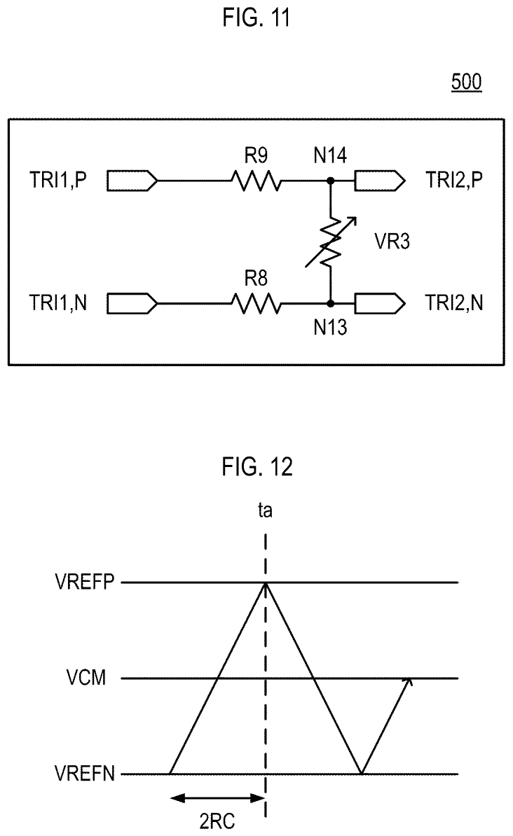

FIG. 11 is a circuit diagram of an adjustment circuit, according to some embodiments.

Referring to FIG. 11, an adjustment circuit 500 (or the adjustment circuit 133 of FIG. 5 or the adjustment circuit included in the tri-wave generation circuit 230 of FIG. 6) according to some embodiments may generate a plurality of differential adjusted tri-wave signals TRI2,N and TRI2,P having different levels from the differential reference tri-wave signals TRI1,N and TRI1,P.

For example, the adjustment circuit 500 may include a plurality of resistors R8 and R9 and one variable resistor VR3. The differential reference tri-wave signals TRI1,N and TRI1,P are provided through the plurality of resistors R8 and R9. The plurality of resistors R8 and R9 are connected to the variable resistor VR3 through a thirteenth node N13 and a fourteenth node N14. The plurality of differential adjusted tri-wave signals TRI2,N and TRI2,P may be output from the thirteenth node N13 and the fourteenth node N14 through the voltage division. The plurality of differential adjusted tri-wave signals TRI2,N and TRI2,P may have levels that differ from those of the differential reference tri-wave signals TRI1,N and TRI1,P.

According to some embodiments, a plurality of adjustment circuits 500 may be provided, allowing differential adjusted tri-wave signals with different levels may be output from each adjustment circuit.

According to the above-described embodiments, the tri-wave signal generation circuit may generate the tri-wave signals with varying levels while maintaining the same common mode voltage VCM. This is achieved through the reference voltage generation circuit 300, the reference tri-wave generation circuit 400, and the adjustment circuit 500. The generated tri-wave signals ensure that the output signal maintains an appropriate duty ratio during operating voltage switching.

FIG. 12 illustrates a waveform of a tri-wave signal output through a tri-wave generation circuit, according to some embodiments.

Referring to FIG. 12, as illustrated, the tri-wave signal may be expressed as a waveform oscillating between the first differential reference voltage VREFN and the second differential reference voltage VREFP based on the common mode voltage VCM. For example, with reference to coefficients “M” and “N” and the operating voltage VBAT described in the reference voltage generation circuit of FIG. 9, the amplitude of the tri-wave signal may be expressed as

$$\frac{M - {V}_{BAT}}{N} = \frac{{V}_{BAT}}{{G}_{PWM}} .$$

Here, the GPWM may be a signal gain, which is N/M.

In addition, with reference to the resistance values “R” of the first variable resistor VR1 and the second variable resistor VR2 and the capacitance values “C” of the third and fourth capacitors C3 and C4 in the reference tri-wave generation circuit 400 of FIG. 10, the half cycle duration of the tri-wave signal, based on “ta,” may be expressed as 2RC, and the switching frequency may be expressed as 1/(4RC).

Ultimately, through the tri-wave generation circuit according to some embodiments, the tri-wave signal may be designed to have a gain determined by parameters in circuits and a switching frequency determined by a resistor and a capacitor in the circuits. This allows for the securement of stable gain and switching frequency. In addition, the tri-wave signal may be designed to have the same common mode voltage VCM regardless of its amplitude level.

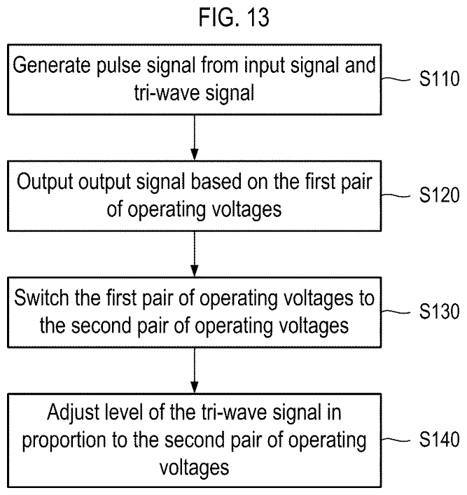

FIG. 13 is a flowchart illustrating a method of operating an amplification device, according to some embodiments.

Referring to FIG. 13, according to some embodiments, in operation S110, the amplification device may generate a pulse signal from an input signal and a tri-wave signal. For example, in operation S110, the pulse signal may be generated by comparing the input signal with the tri-wave signal. The pulse cycle of the pulse signal may be proportional to the instantaneous value of the input signal.

In operation S120, the amplification device may output an output signal corresponding to the pulse signal based on a first pair of operating voltages among the plurality of operating voltages. The plurality of operating voltages may include different multi-level voltages, including a ground voltage. The magnitudes of the low level and the high level of the output signal having the binary pulse may be determined according to the first pair of operating voltages. In other words, the magnitudes of the low and high levels of the output signal, which has a binary pulse, may be determined by the first pair of operating voltages.

In operation S130, the amplification device may switch the first pair of operating voltages to the second pair of operating voltages. Operation S130, which involves performing the switching, may be executed depending on the level change of the input signal. The second pair of operating voltages after the switching may be different from the first pair of operating voltages, or may be common with respect to one operating voltage. In other words, the second pair of operating voltages after the switching may differ from the first pair of operating voltages, or one of the operating voltages may remain common between the two pairs.

In operation S140, the amplification device may adjust the level of the tri-wave signal in proportion to the second pair of operating voltages based on the condition that the first pair of operating voltages are changed to the second pair of operating voltages. Both the level-adjusted tri-wave signal and the tri-wave signal before level adjustment may have the same common mode voltage. In detail, only the amplitude of the tri-wave signal may be adjusted based on the same common mode voltage.

According to the operation method described in the above embodiments, the level

of the tri-wave signal may change along with the switching of the multi-level operating voltage of the amplification device. The adjusted level of the tri-wave signal ensures that the output signal has an appropriate duty ratio, thereby preventing linearity deterioration.

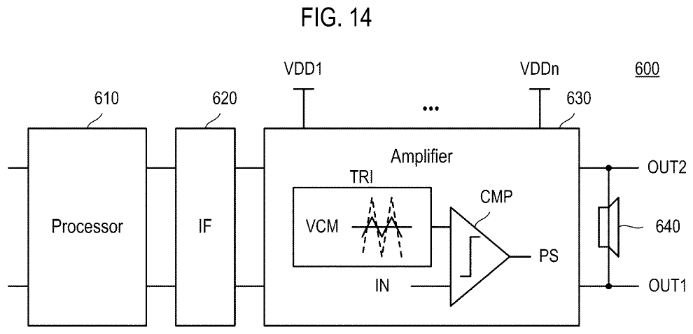

FIG. 14 illustrates an audio device, according to some embodiments.

Referring to FIG. 14, an audio device 600 according to some embodiments may include a processor 610, an interface 620, an amplifier 630, and an audio output device 640.

The processor 610 may perform various processing on digital audio signals. For example, the processor 610 may perform sampling rate change, filter application, interpolation processing, amplification or attenuation of a frequency band, noise processing, channel change, mixing, extraction of a specified signal, etc. on the digital audio signals.

The interface 620 may include an analog-to-digital converter (ADC) and/or a digital-to-analog converter (DAC). The interface 620 may convert a digital audio signal into an analog audio signal, or may convert an analog audio signal into a digital audio signal.

The amplifier 630 may receive the analog audio signal as the input signal IN from the interface 620, may amplify the input signal IN, and may output an output signal. The amplifier 630 may be implemented including the amplification device according to the above-described embodiments (e.g., FIGS. 1 to 13), or may be configured to perform the functions of the amplification device. According to some embodiments, the amplifier 630 may operate according to a plurality of operating voltages having multi-levels, including the voltages VDD1 to VDDn and a ground voltage. When the levels of a pair of operating voltages are switched, the amplifier 630 may generate the pulse signal PS by comparing the tri-wave signal TRI with the changed level to the input signal IN through a comparator CMP. The amplifier 630 may output the output signals OUT1 and OUT2 through the pull-up operation or the pull-down operation based on the pulse signal PS.

The audio output device 640 may be implemented as a speaker that outputs sound depending on the output signals OUT1 and OUT2 output from the amplifier 630. Alternatively, the audio output device 640 may include a receiver that receives sound. Alternatively, the audio output device 640 may include a plurality of speakers and may output sound through a plurality of different channels.

The audio device 600 according to the above-described embodiments may operate based on operating voltages having multi-levels, thereby reducing standby current. In addition, when the operating voltage changes during multi-level operation, the audio device 600 may improve the deterioration in linearity of the output signal by adjusting the level of the tri-wave signal TRI according to the changed level.

According to an embodiment of the present disclosure, the amplification device capable of improving linearity and the method operating the same is provided.

The above descriptions detail specific embodiments of the present disclosure. Modifications that involve simple design changes simply or can be easily implemented may also fall within the scope of the present disclosure. In addition, technologies that can be readily modified or adapted using the above embodiments are included in the present disclosure. Although the present disclosure has been described with reference to these embodiments, it will be apparent to those of ordinary skill in the art that various changes and modifications may be made without departing from the spirit and scope of the present disclosure as set forth in the following claims.

What is claimed is:

1. An amplification device comprising:
a pulse generation circuit configured to generate a pulse signal from an input signal and a tri-wave signal;
a driver circuit configured to output an output signal corresponding to the pulse signal, based on a first pair of operating voltages among a plurality of operating voltages; and
a tri-wave generation circuit configured to generate the tri-wave signal, and to adjust a level of the tri-wave signal in proportion to a second pair of operating voltages, when the first pair of operating voltages is changed to the second pair of operating voltages.

2. The amplification device of claim 1, wherein the pulse generation circuit includes:
a loop filter configured to output an error signal by filtering the input signal and a signal fed back from the output signal; and
a comparator configured to generate the pulse signal by comparing the error signal with the tri-wave signal.

3. The amplification device of claim 1, wherein the driver circuit includes:
a switching network circuit configured to output the output signal through a pull-up or a pull-down operation corresponding to the first pair of operating voltages; and
a gate driver configured to apply a plurality of control signals, based on the pulse signal, to the switching network circuit to control the switching network circuit.

4. The amplification device of claim 3, wherein the switching network circuit includes:
a plurality of pull-up transistors including sources connected to the plurality of operating voltages, gates for receiving some of the plurality of control signals, and drains connected to an output terminal through which the output signal is output; and
a pull-down transistor including a drain connected to the output terminal, a gate for receiving some of the plurality of control signals, and a source connected to ground.

5. The amplification device of claim 3, wherein the plurality of control signals are used to select the first pair of operating voltages or the second pair of operating voltages from among the plurality of operating voltages, based on a level of the input signal.

6. The amplification device of claim 1, wherein the tri-wave generation circuit is configured to generate the tri-wave signal with a same common mode voltage.

7. The amplification device of claim 1, wherein the tri-wave generation circuit includes:
a reference voltage generation circuit configured to generate a reference voltage;
a reference tri-wave generation circuit configured to generate a reference tri-wave signal from the reference voltage;
an adjustment circuit configured to generate one or more adjusted tri-wave signals with different levels from the reference tri-wave signal; and
selection logic configured to select the reference tri-wave signal or the one or more adjusted tri-wave signals, based on when the first pair of operating voltages is changed to the second pair of operating voltages.

8. The amplification device of claim 2, wherein the pulse generation circuit includes:
a feedback loop connected to an input terminal of the loop filter and an output terminal through which the output signal is output, and configured to provide the fed back signal to the input terminal of the loop filter.

9. The amplification device of claim 1, wherein the driver circuit adjusts the first pair of operating voltages to the second pair of operating voltages in response to a change in a level of the input signal.

10. The amplification device of claim 1, wherein the tri-wave generation circuit is configured to:
adjust the level of the tri-wave signal at its maximum or minimum points.

11. An amplification device comprising:
a pair of amplification circuits configured to generate differential pulse signals from differential input signals, a common mode signal, and differential tri-wave signals, and to output differential output signals corresponding to the differential pulse signals, based on a first pair of operating voltages; and
a tri-wave generation circuit configured to generate the differential tri-wave signals, and to adjust levels of the differential tri-wave signals in proportion to a second pair of operating voltages, when the first pair of operating voltages is switched to the second pair of operating voltages.

12. The amplification device of claim 11, wherein the pair of amplification circuits includes:
a pair of loop filters configured to output differential error signals by filtering the differential input signals, the common mode signal, and signals fed back from the differential output signals;
a pair of comparators configured to generate the differential pulse signals by comparing the differential error signals with the differential tri-wave signals; and
a pair of feedback loops connected to input terminals of the pair of loop filters and output terminals that output the differential output signals, and configured to provide the fed back signals to the input terminals of the pair of loop filters.

13. The amplification device of claim 11, wherein the tri-wave generation circuit is configured to generate the differential tri-wave signals with a same common mode voltage.

14. The amplification device of claim 11, wherein the pair of amplification circuits includes:
a pair of driver circuits configured to output the differential output signals through a pull-up or pull-down operation corresponding to the first pair of operating voltages, based on the differential pulse signals.

15. The amplification device of claim 11, wherein the tri-wave generation circuit includes:
a reference voltage generation circuit configured to generate a reference voltage;
a reference tri-wave generation circuit configured to generate differential reference tri-wave signals from the reference voltage;
an adjustment circuit configured to generate a plurality of differential adjusted tri-wave signals with different levels from the differential reference tri-wave signals; and
selection logic configured to select the differential reference tri-wave signals or the plurality of differential adjusted tri-wave signals, when the first pair of operating voltages is switched to the second pair of operating voltages.

16. The amplification device of claim 11, wherein the pair of amplification circuits adjusts the first pair of operating voltages to the second pair of operating voltages in response to a change in a level of the differential input signals.

17. The amplification device of claim 11, wherein the tri-wave generation circuit is configured to:
adjust the levels of the differential tri-wave signals at their maximum or minimum points.

18. A method of operating an amplification device comprising:
generating a pulse signal from an input signal and a tri-wave signal;
outputting an output signal corresponding to the pulse signal, based on a first pair of operating voltages;
switching the first pair of operating voltages to a second pair of operating voltages; and
adjusting a level of the tri-wave signal in proportion to a second pair of operating voltages, when the first pair of operating voltages is switched to the second pair of operating voltages.

19. The method of claim 18, wherein the tri-wave signal has a same common mode voltage.

20. The method of claim 18, wherein the switching of the first pair of operating voltages is performed in response to a change in a level of the input signal.
